(19) United States
(12) Patent Application Publication
(10) Pub. No.: US 2014/0203246 A1
(43) Pub. Date: Jul. 24, 2014

(54) Diode and Display Panel

(71) Applicants: Chih-che Liu, Shenzhen City (CN); Yi-Fan Wang, Shenzhen City (CN)

(72) Inventors: Chih-che Liu, Shenzhen City (CN); Yi-Fan Wang, Shenzhen City (CN)

(73) Assignee: Shenzhen China Star Optoelectronics Technology Co., Ltd., Shenzhen, Guangdong (CN)

(21) Appl. No.: 13/813,954

(22) PCT Filed: Jan. 25, 2013
(86) PCT No.: PCT/CN2013/070971

§ 371 Date: Feb. 4, 2013

(30) Foreign Application Priority Data
Jan. 23, 2013 (CN) 201310024995.0

(51) Int. Cl. H01L 51/50

(52) U.S. Cl. CPC H01L 51/5072
USPC 257/40

(57) ABSTRACT

The present invention provides a diode and display panel, which includes: cathode and anode; wherein, cathode and anode being disposed relatively. Electron transport layer is disposed between cathode and anode. Electron transport layer is doped with alkali metal compounds, which is a material used to form electron injection layers. Alkali metal compounds comprise at least one of the materials from lithium metaborate, potassium silicate, lithium tetra (8-hydroxyquinolinato) boron, and alkali metal acetate. The present invention improves the light-emitting performance, lowers operating voltage, simplifies the manufacturing process, and increases the yield rate; as a result, to reduce the cost of diodes.

### BACKGROUND OF THE INVENTION

1. Field of the Invention

The present invention relates to the field of displaying techniques, and in particular to diode and display panel.

2. The Related Arts

The diode is a semiconductor; an organic light-emitting diode (OLED), as known as an organic electroluminesence display (OELD), is a semiconductor with light emission function. OLED possesses advantages of a cathode ray tube (CRT) and liquid crystal display (LCD). OLED is also known as display devices of tablets of the 21st century and the 3rd generation display techniques. OLED has become a spotlight in the future research in the present global environment.

The OLED basically comprises a thin transparent indium tin oxide (ITO) with characteristics of semiconductor connecting to an anode of power supply and a metallic cathode. The structure of the OLED is like a sandwich. The structure of layers comprises: hole transport layer (HTL), emission layer (EL), and electron transport layer (ETL). When power supply increases the voltage to certain level, electric charges from anode holes and cathode meet in the emission layer to produce lights. The different combinations produce red, green, and blues lights to form the basic colors.

Ever since the OLED introduced, many researchers focused on improving the light-emitting performance and lowering operating voltage. In order to improve the performance and lower operating voltage of the diode, an electron transport layer and electron injection layer are added and inserted between emission layer and electrodes. However, the complexity of manufacturing process does not only raise the cost of equipments but also lower the yield rate.

### SUMMARY OF THE INVENTION

The technical issue to be addressed by the present invention is to provide a diode and display panel to improve the light-emitting performance, lower operating voltage, simplify the manufacturing process, and increase the yield rate; as a result, to reduce the cost of diodes.

The present invention provides a diode, which comprises: cathode and anode; wherein, cathode and anode being disposed relatively; electron transport layer being disposed between cathode and anode; electron transport layer being doped with alkali metal compounds, which being a material used to form electron injection layers; alkali metal compounds comprising at least one of the materials from lithium metaborate, potassium silicate, lithium tetra (8-hydroxyquinolinato) boron, and alkali metal acetate; wherein, alkali metal acetate comprising at least one of the materials from lithium acetate, sodium acetate, potassium acetate, rubidium acetate, and cesium acetate; alkali metal compounds also comprising at least one of the materials from alkali metal oxides and alkali metal halides.

The present invention provides a diode, which comprises: cathode and anode; wherein, cathode and anode being disposed relatively; electron transport layer being disposed between cathode and anode; electron transport layer being doped with alkali metal compounds, which being a material used to form electron injection layers; alkali metal compounds comprising at least one of the materials from lithium metaborate, potassium silicate, lithium tetra (8-hydroxyquinolinato) boron, and alkali metal acetate.

According to a preferred embodiment of the present invention, alkali metal acetate comprises at least one of the materials from lithium acetate, sodium acetate, potassium acetate, rubidium acetate, and cesium acetate.

According to a preferred embodiment of the present invention, alkali metal compounds also comprise at least one of the materials from alkali metal oxides and alkali metal halides.

According to a preferred embodiment of the present invention, alkali metal halides are alkali metal fluoridesthe.

According to a preferred embodiment of the present invention, the electron transport layer is doped with at least two alkali metal compounds, which is a material used to form electron injection layers; wherein, at least one of alkali metal compounds being one of the materials from lithium metaborate, potassium silicate, lithium tetra (8-hydroxyquinolinato) boron, and alkali metal acetate.

According to a preferred embodiment of the present invention, when the electron transport layer is doped with one alkali metal compound, which is a material used to form electron injection layers, amount of the doped alkali metal compound is five wt % to fifty wt % of the electron transport layer; when the electron transport layer is doped with at least one of alkali metal compounds, which is a material used to form electron injection layers, amount of the doped alkali metal compounds is one wt % to fifty wt % of the electron transport layer.

According to a preferred embodiment of the present invention, when the electron transport layer is doped with one alkali metal compound, which is a material used to form electron injection layers, amount of the doped alkali metal compound is fifteen wt % to twenty-five wt % of the electron transport layer; when the electron transport layer is doped with at least one of alkali metal compounds, which is a material used to form electron injection layers, amount of the doped alkali metal compounds is ten wt % to fifteen wt % of the electron transport layer.

According to a preferred embodiment of the present invention, the diode comprises an emission layer being disposed between anode and the electron transport layer.

According to a preferred embodiment of the present invention, the diode comprises at least one hole transport layer or hole injection layer, which is disposed between anode and the emission layer being disposed between anode and the electron transport layer.

The present invention provides a display panel, which comprises: a diode comprising cathode and anode; wherein, cathode and anode being disposed relatively; electron transport layer being disposed between cathode and anode; electron transport layer being doped with alkali metal compounds, which being a material used to form electron injection layers; alkali metal compounds comprising at least one of the materials from lithium metaborate, potassium silicate, lithium tetra (8-hydroxyquinolinato) boron, and alkali metal acetate.

According to a preferred embodiment of the present invention, alkali metal acetate comprises at least one of the materials from lithium acetate, sodium acetate, potassium acetate, rubidium acetate, and cesium acetate.

According to a preferred embodiment of the present invention, alkali metal compounds also comprise at least one of the materials from alkali metal oxides and alkali metal halides.

According to a preferred embodiment of the present invention, alkali metal halides are alkali metal fluoridesthe.

According to a preferred embodiment of the present invention, the electron transport layer is doped with at least two alkali metal compounds, which is a material used to form electron injection layers; wherein, at least one of alkali metal compounds being one of the materials from lithium metaborate, potassium silicate, lithium tetra (8-hydroxyquinolinato) boron, and alkali metal acetate.

According to a preferred embodiment of the present invention, when the electron transport layer is doped with one alkali metal compound, which is a material used to form electron injection layers, amount of the doped alkali metal compound is five wt % to fifty wt % of the electron transport layer; when the electron transport layer is doped with at least one of alkali metal compounds, which is a material used to form electron injection layers, amount of the doped alkali metal compounds is one wt % to fifty wt % of the electron transport layer.

According to a preferred embodiment of the present invention, when the electron transport layer is doped with one alkali metal compound, which is a material used to form electron injection layers, amount of the doped alkali metal compound is fifteen wt % to twenty-five wt % of the electron transport layer; when the electron transport layer is doped with at least one of alkali metal compounds, which is a material used to form electron injection layers, amount of the doped alkali metal compounds is ten wt % to fifteen wt % of the electron transport layer.

According to a preferred embodiment of the present invention, the diode comprises an emission layer being disposed between anode and the electron transport layer.

According to a preferred embodiment of the present invention, the diode comprises at least one hole transport layer or hole injection layer, which is disposed between anode and the emission layer being disposed between anode and the electron transport layer.

### BRIEF DESCRIPTION OF THE DRAWINGS

FIG. 1 is a schematic view showing the structure of an embodiment of the diode according to the present invention;

FIG. 2 is a schematic view showing the relationship of current density and voltage of the diode;

FIG. 3 is a schematic view showing the relationship of brightness and voltage of the diode;

FIG. 4 is a schematic view showing the relationship of current efficiency and brightness of the diode;

FIG. 5 is another schematic view showing the structure of an embodiment of the diode according to the present invention.

### DETAILED DESCRIPTION OF THE PREFERRED EMBODIMENTS

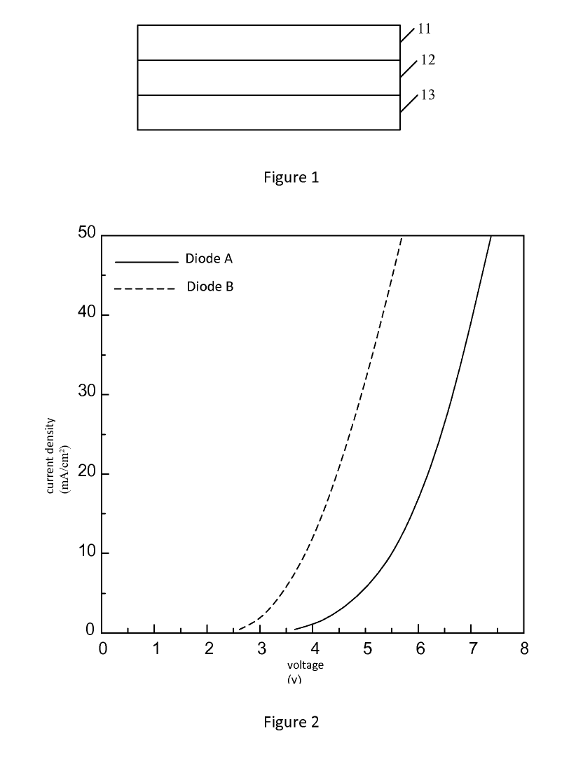

Referring to FIG. 1, FIG. 1 is a schematic view showing the structure of an embodiment of the diode according to the present invention. The diode comprises: cathode 11 and anode 13; wherein, cathode 11 and anode 13 being disposed relatively; electron transport layer 12 being disposed between cathode 11 and anode 13; electron transport layer 12 being doped with alkali metal compounds, which is a material used to form electron injection layers; wherein, alkali metal compounds comprising at least one of the materials from lithium metaborate (LiBO₂), potassium silicate (K₂SiO₃), lithium tetra (8-hydroxyquinolinato) boron (Liq), and alkali metal acetate; alkali metal acetate comprises at least one of the materials from lithium acetate (CH₃COOLi), sodium acetate (CH₃COONa), potassium acetate (CH₃COOK), rubidium acetate (CH₃COORb), and cesium acetate (CH₃COOCs)

As an example, alkali metal compounds can be LiBO₂, or the combination of K₂SiO₃ and CH₃COOLi, or the combination of Liq, CH₃COONa, and K₂SiO₃. The combinations can be changed according to the needs.

In another embodiment, alkali metal compounds can also comprise at least one of the materials from alkali metal oxides and alkali metal halides. Wherein, alkali metal oxides can be at least one material of lithium oxide (Li₂O) or cesium oxide (Cs₂O₃), and Alkali metal halides can be at least one material of lithium fluoride (LiF), sodium fluoride (NaF), potassium fluoride (KF), rubidium fluoride (RbF), and cesium fluoride (CsF).

In the instant embodiment, according to a preferred embodiment of the present invention, the electron transport layer is doped with at least two alkali metal compounds, which is a material used to form electron injection layers; wherein, at least one of alkali metal compounds being one of the materials from LiBO₂, K₂SiO₃, Liq, and alkali metal acetate. The electron transport layer doped with at least two alkali metal compounds, which is a material used to form electron injection layers, has lower supply voltage and better current efficiency than the electron transport layer doped with only one alkali metal compound.

As an example, alkali metal compounds can be Lif and LiBO₂, or the combination of CH₃COOCs, NaF, RbF, and Li₂O. The materials and combinations can be changed according to the needs in practice.

In addition, the amount of alkali metal compounds used is a key element to the performance of the diode. Too many or few amount of alkali metal compounds can not improve to the performance of the diode; in some cases, too many or few amount of alkali metal compounds can lower the performance of the diode. When the electron transport layer is doped with one alkali metal compound, which is a material used to form electron injection layers, amount of the doped alkali metal compound should be five wt % to fifty wt % of the electron transport layer. According to a preferred embodiment of the present invention, when the electron transport layer is doped with one alkali metal compound, the amount of the doped alkali metal compound is fifteen wt % to twenty-five wt % of the electron transport layer; twenty wt % of the electron transport layer as an example. When the electron transport layer is doped with at least one (two or more than two) of alkali metal compounds, which is a material used to form electron injection layers, the amount of alkali metal compounds used is a key element directly to the performance of the diode. In the instant embodiment, according to a preferred embodiment of the present invention, the amount of the doped alkali metal compounds is one wt % to fifty wt % of the electron transport layer. According to a preferred embodiment of the present invention when the electron transport layer is doped with at least one of alkali metal compounds, which is a material used to form electron injection layers, amount of the doped alkali metal compounds is ten wt % to fifteen wt % of the electron transport layer.

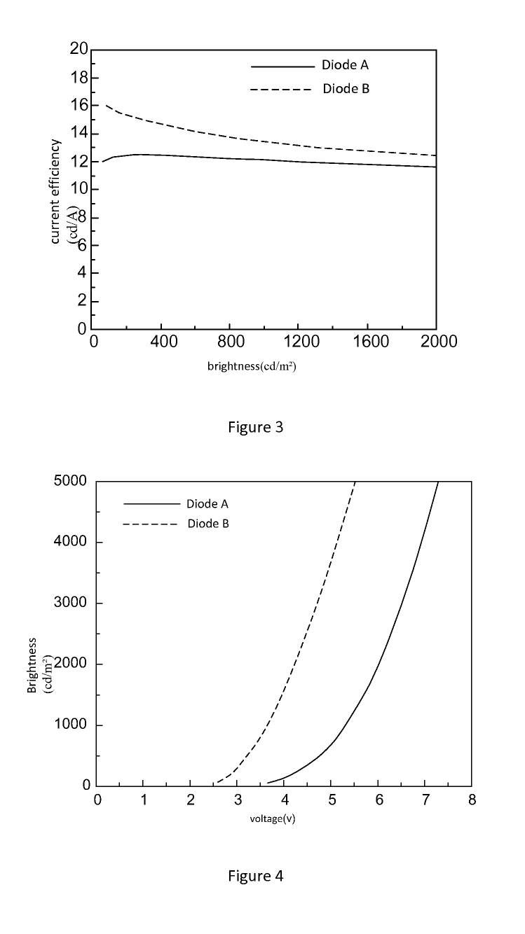

In the instant embodiment, one diode with the electron transport layer is doped twenty wt % of the electron transport layer of LiF (hereinafter “diode A”), and the other diode with the electron transport layer is doped fifteen wt % of the electron transport layer of LIF and ten wt % of the electron transport layer of Liq (hereinafter “diode B”). The comparison of diode A and diode B is presented in Figures; wherein, referring to FIGS. 2, 3, and 4. FIG. 2 is a schematic view showing the relationship of current density and voltage of the diode. FIG. 3 is a schematic view showing the relationship of brightness and voltage of the diode. FIG. 4 is a schematic view showing the relationship of current efficiency and brightness of the diode.

Comparing with 2 diodes, when the current density is at 50 mA/cm², the supply voltage of diode B is 1.7V lower than the supply voltage of diode A. As a result, by changing to the ratio of two materials, the diode doped two alkali metal compounds has a better performance in brightness and supply voltage than the diode doped one alkali metal compound. Therefore, two or more alkali metal compounds are used to improve the performance of the diodes in practice.

In the instant embodiment, anode can be transparent conductive film; indium tin oxide (ITO) as an example. Cathode can be metal; aluminum and copper, as examples

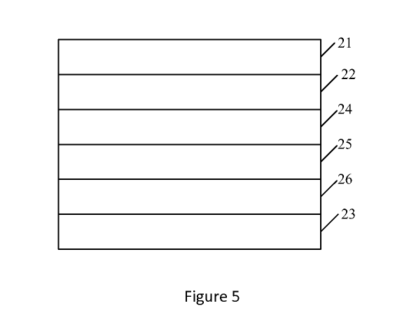

As shown in FIG. 5 is another schematic view showing the structure of an embodiment of the diode according to the present invention. The diode comprises: cathode 21, anode 23, and electron transport layer 22. The diode can comprise emission layer 24 being disposed between anode 23 and electron transport layer 22 to make the light-emitting diode; adding blue light emission layer 24 being disposed between anode 23 and electron transport layer 22 to make the blue light-emitting diode, as an example.

Furthermore, in order to improve the electron transport, hole transport, and, hole injection, the diode can comprise either hole transport layer 25 or hole injection layer 26, or both hole transport layer 25 and hole injection layer 26 simultaneously disposed between anode 23 and emission layer 24. Wherein, when the diode comprises both hole transport layer 25 and hole injection layer 26, the relative position of hole transport layer 25 and hole injection layer 26 is not fixed. The materials to form hole transport layer 25 and hole injection layer 26 can be normal materials to form other hole transport layers and hole injection layers in conventional process.

The present invention of diode can be manufactured in conventional process. First, top electrode and button electrode are plated on glass plate, wherein, the button electrode can be cathode or anode. Secondly, referring to FIGS. 1 2, 3, 4, and 5, alkali metal compounds, which is a material used to form electron injection layers, are deposited to dope electron transport layer, emission layer, and hole transport layer. After completing these structural layers, top electrode and button electrode are plated. When top electrode is cathode, button electrode is anode. When top electrode is anode, button electrode is cathode. The relative position of anode, or cathode, and glass plate can be changed. However, the relative position of other structural layers and anode, or cathode, cannot be changed.

The present invention provides a display panel, which comprises: a diode in the embodiments of the present invention described above.

In the embodiments of the present invention described above, the present invention of the diode comprises the electron transport layer being doped with alkali metal compounds, which is a material used to form electron injection layers. Therefore, the electron transport layer of the present invention of the diode can replace the electron layer and electron injection layer in known technique. The present invention improves the light-emitting performance, lowers operating voltage, simplifies the manufacturing process, and increases the yield rate; as a result, to reduce the cost of diodes.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed is:

1. The present invention provides a diode, which comprises:
cathode and anode;
wherein, cathode and anode being disposed relatively;
electron transport layer being disposed between cathode and anode;
electron transport layer being doped with alkali metal compounds, which is a material used to form electron injection layers;
alkali metal compounds comprising at least one of the materials from lithium metaborate, potassium silicate, lithium tetra (8-hydroxyquinolinato) boron, and alkali metal acetate; and,
wherein, alkali metal acetate comprising at least one of the materials from lithium acetate, sodium acetate, potassium acetate, rubidium acetate, and cesium acetate; alkali metal compounds also comprising at least one of the materials from alkali metal oxides and alkali metal halides.

2. The present invention provides a diode, which comprises:
cathode and anode;
wherein, cathode and anode being disposed relatively;
electron transport layer being disposed between cathode and anode;
electron transport layer being doped with alkali metal compounds, which being a material used to form electron injection layers; and,
alkali metal compounds comprising at least one of the materials from lithium metaborate, potassium silicate, lithium tetra (8-hydroxyquinolinato) boron, and alkali metal acetate.

3. The diode as claimed in claim 2, characterized in that:
alkali metal acetate comprises at least one of the materials from lithium acetate, sodium acetate, potassium acetate, rubidium acetate, and cesium acetate.

4. The diode as claimed in claim 2, characterized in that:
alkali metal compounds also comprise at least one of the materials from alkali metal oxides and alkali metal halides.

5. The diode as claimed in claim 4, characterized in that:
alkali metal halides are alkali metal fluoridesthe.

6. The diode as claimed in claim 2, characterized in that:
the electron transport layer is doped with at least two alkali metal compounds, which is a material used to form electron injection layers; and,
wherein, at least one of alkali metal compounds being one of the materials from lithium metaborate, potassium silicate, lithium tetra (8-hydroxyquinolinato) boron, and alkali metal acetate.

7. The diode as claimed in claim 2, characterized in that:
when the electron transport layer is doped with one alkali metal compound, which is a material used to form electron injection layers, amount of the doped alkali metal compound is five wt % to fifty wt % of the electron transport layer; and,
when the electron transport layer is doped with at least one of alkali metal compounds, which is a material used to form electron injection layers, amount of the doped alkali metal compounds is one wt % to fifty wt % of the electron transport layer.

8. The diode as claimed in claim 7, characterized in that:
when the electron transport layer is doped with one alkali metal compound, which is a material used to form electron injection layers, amount of the doped alkali metal compound is fifteen wt % to twenty-five wt % of the electron transport layer; and,
when the electron transport layer is doped with at least one of alkali metal compounds, which is a material used to form electron injection layers, amount of the doped alkali metal compounds is ten wt % to fifteen wt % of the electron transport layer.

9. The diode as claimed in claim 2, characterized in that:
the diode comprises an emission layer being disposed between anode and the electron transport layer.

10. The diode as claimed in claim 9, characterized in that:
the diode comprises at least one hole transport layer or hole injection layer, which is disposed between anode and the emission layer being disposed between anode and the electron transport layer.

11. The present invention provides a display panel, which comprises:
a diode comprising cathode and anode;
wherein, cathode and anode being disposed relatively;
electron transport layer being disposed between cathode and anode;
electron transport layer being doped with alkali metal compounds, which being a material used to form electron injection layers; and,
alkali metal compounds comprising at least one of the materials from lithium metaborate, potassium silicate, lithium tetra (8-hydroxyquinolinato) boron, and alkali metal acetate.

12. The display panel as claimed in claim 11, characterized in that:
alkali metal acetate comprises at least one of the materials from lithium acetate, sodium acetate, potassium acetate, rubidium acetate, and cesium acetate.

13. The display panel as claimed in claim 11, characterized in that:
alkali metal compounds also comprise at least one of the materials from alkali metal oxides and alkali metal halides.

14. The display panel as claimed in claim 13, characterized in that:
alkali metal halides are alkali metal fluoridesthe.

15. The display panel as claimed in claim 11, characterized in that:
the electron transport layer is doped with at least two alkali metal compounds, which is a material used to form electron injection layers;
wherein, at least one of alkali metal compounds being one of the materials from lithium metaborate, potassium silicate, lithium tetra (8-hydroxyquinolinato) boron, and alkali metal acetate.

16. The display panel as claimed in claim 11, characterized in that:
when the electron transport layer is doped with one alkali metal compound, which is a material used to form electron injection layers, amount of the doped alkali metal compound is five wt % to fifty wt % of the electron transport layer;
when the electron transport layer is doped with at least one of alkali metal compounds, which is a material used to form electron injection layers, amount of the doped alkali metal compounds is one wt % to fifty wt % of the electron transport layer.

17. The display panel as claimed in claim 16, characterized in that:
when the electron transport layer is doped with one alkali metal compound, which is a material used to form electron injection layers, amount of the doped alkali metal compound is fifteen wt % to twenty-five wt % of the electron transport layer;
when the electron transport layer is doped with at least one of alkali metal compounds, which is a material used to form electron injection layers, amount of the doped alkali metal compounds is ten wt % to fifteen wt % of the electron transport layer.

18. The display panel as claimed in claim 11, characterized in that:
the diode comprises an emission layer being disposed between anode and the electron transport layer.

19. The display panel as claimed in claim 18, characterized in that:
the diode comprises at least one hole transport layer or hole injection layer, which is disposed between anode and the emission layer being disposed between anode and the electron transport layer.
